(19) United States
(12) Patent Application Publication
(10) Pub. No.: US 2012/0074485 A1
(43) Pub. Date: Mar. 29, 2012

(54) Nonvolatile Memory Device and Manufacturing Method Thereof

(75) Inventors: Chul Young Ham, Guri-si (KR); Min Sik Jang, Icheon-si (KR); Sang Soo Lee, Songpa-gu (KR)

(73) Assignee: HYNIX SEMICONDUCTOR INC., Icheon-si (KR)

(21) Appl. No.: 13/312,569

(22) Filed: Dec. 6, 2011

Related U.S. Application Data
(63) Continuation-in-part of application No. 12/972,117, filed on Dec. 17, 2010.

(30) Foreign Application Priority Data
Dec. 30, 2009 (KR) 10-2009-0134122

(51) Int. Cl. H01L 29/788; H01L 21/336

(52) U.S. Cl. 257/316; 438/593; 257/E29.3; 257/E21.422

(57) ABSTRACT

A nonvolatile memory device comprises a gate insulating layer, a floating gate and a dielectric layer sequentially formed over a semiconductor substrate, a capping layer formed over the dielectric layer, and a control gate formed over the capping layer, wherein the control gate includes nitrogen or carbon as an additive.

### CROSS-REFERENCE TO RELATED APPLICATION

Priority to Korean patent application number 10-2009-0134122 filed Dec. 30, 2009, the entire disclosure of which is incorporated by reference herein, is claimed.

### BACKGROUND

Exemplary embodiments relate generally to a method of manufacturing nonvolatile memory devices and, more particularly, to a method of manufacturing nonvolatile memory devices that is capable of preventing the generation of voids when forming a control gate.

A nonvolatile memory device includes a floating gate for storing data and a control gate for transferring driving voltages.

A method of forming the nonvolatile memory device is described below.

A gate insulating layer and a conductive layer for floating gates are formed over a semiconductor substrate. The conductive layer and the gate insulating layer are patterned to expose the semiconductor substrate, and some of the exposed semiconductor substrate is etched to form trenches for isolation. The trenches are filled with an insulating material to form isolation layers, and an etch process for lowering the height of the isolation layers is performed. A dielectric layer is formed on the entire surface, and a conductive layer for control gates is formed over the dielectric layer.

Meanwhile, with increases in the degree of integration of nonvolatile memory devices, not only the width of the floating gate, but also a gap between neighboring floating gates is narrowed.

Accordingly, after forming the dielectric layer, when forming the conductive layer for control gates, voids can be generated between the conductive layers for floating gates. Thus, voids can be generated on a surface of the dielectric layer and in the control gates.

If voids are generated as described above, resistance of the control gate can be increased when the memory device is operated, and there may be a difference in the electrical characteristics between a region in which voids have occurred and a region in which voids have not occurred. Accordingly, reliability of the nonvolatile memory device may be degraded.

### BRIEF SUMMARY

Exemplary embodiments relate to a method of manufacturing nonvolatile memory devices that is capable of preventing the generation of voids in a process of forming a control gate.

A nonvolatile memory device according to an aspect of the disclosure comprises a gate insulating layer, a floating gate and a dielectric layer sequentially formed over a semiconductor substrate, a capping layer formed over the dielectric layer, and a control gate formed over the capping layer, wherein the control gate includes polysilicon in which nitrogen or carbon as an additive is contained.

A nonvolatile memory device according to an aspect of the disclosure comprises a gate insulating layer, floating gate and dielectric layer sequentially formed over a semiconductor substrate, a capping layer formed over the dielectric layer, and a control gate formed over the capping layer, wherein the control gate contains additive for having a nano sized grain.

A nonvolatile memory device according to an aspect of the disclosure comprises a gate insulating layer and a floating gate and dielectric layer sequentially formed over a semiconductor substrate of an active region defined by isolation layers, a dielectric layer formed along a surface of the isolation layers and the floating gate, a capping layer formed along a surface of the dielectric layer, and a control gate formed over the capping layer, wherein the control gate contains nitrogen or carbon as an additive for a nano sized grain.

A method of manufacturing nonvolatile memory devices according to an aspect of the disclosure comprises forming a sequentially stacked gate insulating layer and a floating gate over a semiconductor substrate, forming a dielectric layer along a surface of a whole structure including the floating gate, forming a capping layer along a surface of the dielectric layer, forming a conductive layer of an amorphous layer over the capping layer, wherein the conductive layer contains additives, performing an annealing process to crystallize the capping layer and the conductive layer, and removing voids or seams which may occur during formation of the conductive layer.

### BRIEF DESCRIPTION OF THE DRAWINGS

FIGS. 1A to 1F are cross-sectional views illustrating a method of manufacturing nonvolatile memory devices according to a first exemplary embodiment of this disclosure;

FIGS. 2A to 2H are cross-sectional views illustrating a method of manufacturing nonvolatile memory devices according to a second exemplary embodiment of this disclosure; and

FIGS. 3A to 3F are cross-sectional views illustrating a method of manufacturing nonvolatile memory devices according to a third exemplary embodiment of this disclosure.

### DESCRIPTION OF EMBODIMENTS

Hereinafter exemplary embodiments of the disclosure are described in detail with reference to the accompanying drawings. The drawing figures are provided to allow those having ordinary skill in the art to understand the scope of the embodiments of this disclosure.

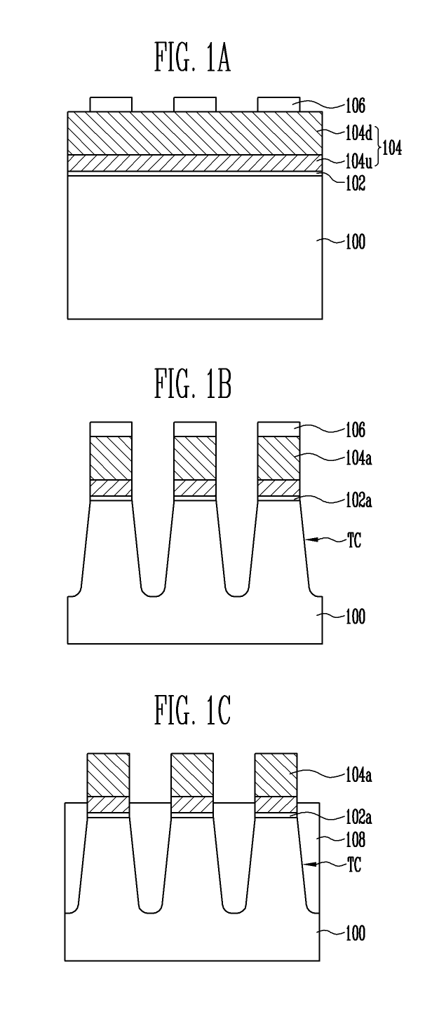

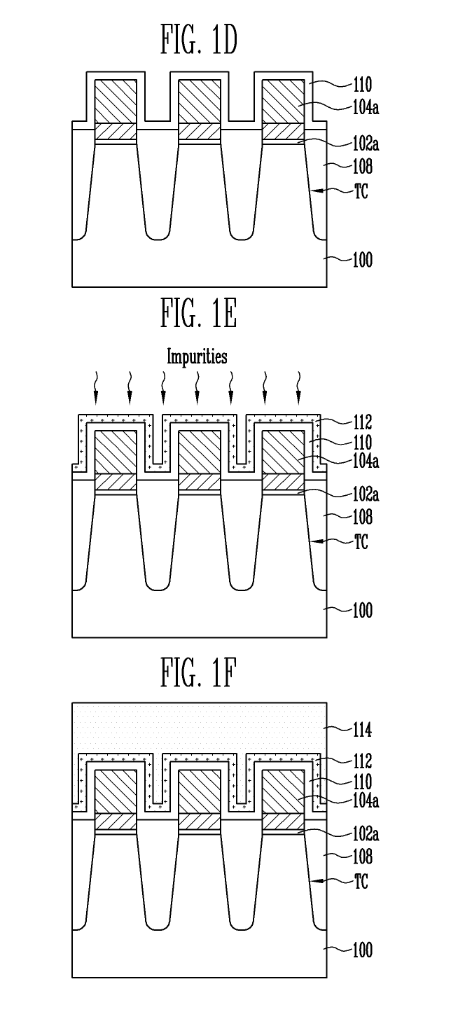

FIGS. 1A to 1F are cross-sectional views illustrating a method of manufacturing nonvolatile memory devices according to an exemplary embodiment of this disclosure.

Referring to FIG. 1A, a gate insulating layer 102, a first conductive layer 104u for a floating gate 104, a second conductive layer 104d, and isolation mask patterns 106 are formed over a semiconductor substrate 100. The gate insulating layer 102 preferably comprises an oxide layer. The first conductive layer 104u preferably comprises an undoped polysilicon layer, and the second conductive layer 104d preferably comprises a doped polysilicon layer. The isolation mask patterns 106 preferably comprise a nitride layer.

Referring to FIG. 1B, the second and first conductive layers (104d and 104u, respectively, of FIG. 1A) and the gate insulating layer (102 of FIG. 1A) are patterned by performing an etch process along the isolation mask patterns 106. Some of the exposed semiconductor substrate 100 is etched to form trenches TC for isolation. Consequently, the gate insulating patterns 102a, the floating gates 104a, and the isolation mask patterns 106 remain over the active regions of the semiconductor substrate 100, and the trenches TC are formed in the isolation regions of the semiconductor substrate 100.

Referring to FIG. 1C, the inside of the trenches TC is filled with an insulating material, thereby forming isolation layers 108. More particularly, to fill the inside of the trenches TC, the insulating material is formed to fully cover the top surface of the isolation mask patterns 106. Next, a polishing process (for example, chemical mechanical polishing (CMP)) is performed until the isolation mask patterns 106 are exposed, thereby isolating the insulating materials filled in the inside of the trenches TC and forming the isolation layers 108. The isolation mask patterns 106 are removed, and the height of the isolation layers 108 is lowered to control the effective field height (EFH). Here, the gate insulating patterns 102a preferably are not exposed.

Referring to FIG. 1D, a dielectric layer 110 is formed on the isolation layers 108 and an exposed surface of the floating gates 104a. The dielectric layer 110 preferably is formed by stacking an oxide layer, a nitride layer, and an oxide layer or by depositing a high-K layer.

Referring to FIG. 1E, a capping layer 112 for easily forming a control gate is formed on a surface of the dielectric layer 110.

More particularly, the capping layer 112 preferably comprises a polysilicon layer and preferably is relatively thin (for example 5 Å to 50 Å) by taking the aspect ratio between the floating gates 104a into consideration.

After forming the capping layer 112, impurities are added to the capping layer 112 for the purpose of prohibiting the generation of voids in a subsequent process of forming a third conductive layer (114 of FIG. 1F) for a control gate. More particularly, the impurities added to the capping layer 112 preferably include at least one of phosphorous (P), nitrogen (N), and oxygen (O). To add the impurities to the capping layer 112, an impurity source gas preferably is supplied to a chamber in which the semiconductor substrate 100 is loaded. More particularly, to add phosphorous (P) in the capping layer 112, PH₃ gas (i.e., an impurity source gas of a high concentration) preferably is supplied to the chamber. To add nitrogen (N) to the capping layer 112, NH₃ gas (i.e., the impurity source gas) preferably is supplied to the chamber. To add oxygen (O) to the capping layer 112, O₂ gas (i.e., the impurity source gas) preferably is supplied to the chamber. Thus, at least one of the PH₃ gas, the NH₃ gas, and the O₂ gas preferably is supplied to the chamber so that the impurities are included in the capping layer 112. The gas supplied to the chamber preferably has a concentration in the chamber of 5×10¹⁹ ion/cm³ to 1×10²² ion/cm³. If at least one of the PH₃ gas, the NH₃ gas, and the O₂ gas of a high concentration is supplied to the chamber, different impurities are included in the capping layer 112 according to the type of the supplied impurity source gas. The capping layer 112 containing the impurities serves as a seed layer when subsequently forming the third conductive layer 114 for a control gate.

The process of adding the impurities in the capping layer 112 preferably is performed in-situ in the same chamber after forming the capping layer 112.

Referring to FIG. 1F, the third conductive layer 114 for a control gate is formed over the capping layer 112 containing the impurities. The third conductive layer 114 preferably comprises a doped polysilicon layer. In particular, if the third conductive layer 114 is formed over the capping layer 112 including the impurities and the seed layer, the impurities and the seed layer serve as an uniform seed of the third conductive layer 114, and a third conductive layer 114 having grains of an uniform size can be formed. Furthermore, the process of forming the third conductive layer 114 preferably is performed in-situ by using the same chamber after the process of adding the impurities to the capping layer 112 is performed. As described above, since the process of forming the capping layer 112, the process of including the impurities, and the process of forming the third conductive layer 114 can be performed in-situ in the same chamber, the turnaround time can be reduced.

Furthermore, since the capping layer 112 containing the impurities is formed, voids can be prevented from occurring on the surface of the dielectric layer 110 or within the third conductive layer 114 in the process of forming the third conductive layer 114. Since the generation of voids is prevented, an increase of resistance of the control gate can be prevented, thereby improving reliability of the nonvolatile memory devices.

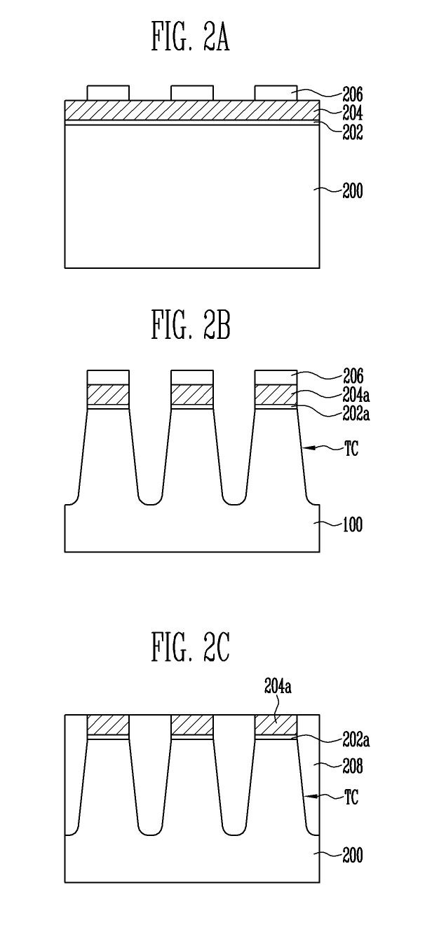

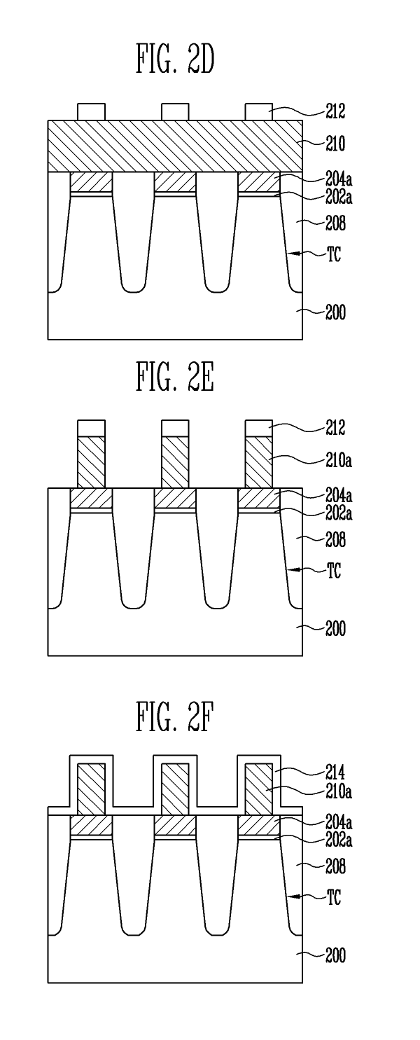

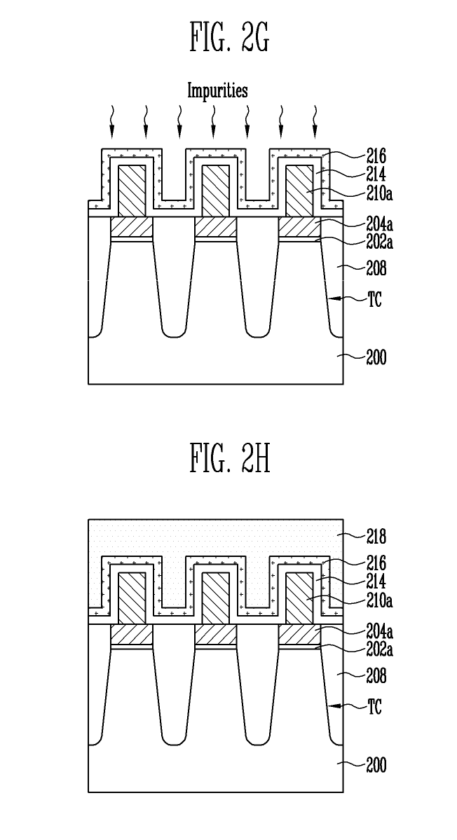

FIGS. 2A to 2H are cross-sectional views illustrating a method of manufacturing nonvolatile memory devices according to another exemplary embodiment of this disclosure.

Referring to FIG. 2A, a gate insulating layer 202, a first conductive layer 204 for floating gates, and isolation mask patterns 206 are formed over a semiconductor substrate 200. The gate insulating layer 202 preferably comprises an oxide layer. The first conductive layer 204 preferably comprises an undoped polysilicon layer, and the isolation mask patterns 206 preferably comprise a nitride layer. Here, the first conductive layer 204 preferably is relatively thin to lower the aspect ratio of trenches (TC of FIG. 2B) in a subsequent process of forming isolation layers (208 of FIG. 2C).

Referring to FIG. 2B, the first conductive layer (204 of FIG. 2A) and the gate insulating layer (202 of FIG. 2A) are patterned by performing an etch process using the isolation mask patterns 206, thereby forming first conductive patterns 204a and gate insulating patterns 202a. Trenches TC are formed by etching some of the exposed semiconductor substrate 200. Here, the trenches TC may have a different aspect ratio depending on the thickness of the first conductive patterns 204a. Thus, if the first conductive patterns 204a are relatively thin, the trenches TC may have a lower aspect ratio, and the generation of voids can be prevented in a gap-fill process of filling the inside of the trenches TC with an insulating material.

Referring to FIG. 2C, the isolation layers 208 are formed within the trenches TC. More particularly, the isolation layers 208 are comprise an insulating material, but may be formed by stacking a fluid insulating layer and a high-density insulating layer to improve the gap-fill characteristic. For example, the bottom of the trenches TC may be filled with a spin on dielectric (SOD) layer (i.e., a fluid insulating material). A thermal treatment process for solidifying the SOD layer is performed because the SOD layer is a fluid material. If the thermal treatment process is performed, the fineness of the SOD layer may be reduced. Accordingly, it is preferred that a high density plasma (HDP) layer (i.e., a high-density insulating layer) be formed over the SOD layer.

Next, the insulating materials are isolated from each other by performing a polishing process (for example, chemical mechanical polishing (CMP)) until the isolation mask patterns (206 of FIG. 2B) are exposed, thereby forming the isolation layers 208. After removing the isolation mask patterns 206, the height of the isolation layers 208 is lowered by performing an etch process to control the effective field height (EFH). Here, the gate insulating patterns 202a are not exposed.

Referring to FIG. 2D, a second conductive layer 210 for floating gates is formed over the isolation layers 208 and the first conductive patterns 204a. The second conductive layer 210 preferably comprises a doped polysilicon layer. The second conductive layer 210 preferably is thicker than first conductive patterns 204a to increase the area of the floating gates. Hard mask patterns 212 for patterning second conductive layer 210 are formed over the second conductive layer 210. The hard mask pattern 212 preferably is narrower than the first conductive pattern 204a.

Referring to FIG. 2E, the second conductive layer 210 is patterned by performing an etch process using the hard mask patterns 212. Thus, second conductive patterns 210a, each being narrower than the first conductive pattern 204a, can be formed over the first conductive patterns 204a for the purpose of lowering the aspect ratio by widening a gap between the second conductive patterns 210a for floating gates upwardly protruding from the isolation layers 208. Thus, in a subsequent process of forming a control gate, voids can be prohibited from occurring in the control gate.

Referring to FIG. 2F, a dielectric layer 214 is formed on a surface of the isolation layers 208 and the first and second conductive patterns 204a and 210a, respectively. The dielectric layer 214 preferably is formed by stacking an oxide layer, a nitride layer, and an oxide layer or by depositing a high-k layer.

Referring to FIG. 2G, a capping layer 216 for easily forming the control gate is formed on a surface of the dielectric layer 214. More particularly, the capping layer 216 preferably comprises a polysilicon layer. The capping layer 216 preferably is formed relatively thin (for example, 5 Å to 50 Å) by taking the aspect ratio between the second conductive patterns 210a into consideration.

After forming the capping layer 216, impurities are added to the capping layer 216 to prevent voids from occurring on the surface of the dielectric layer 214 or within the control gate in a subsequent process of forming a third conductive layer (218 of FIG. 2H) for the control gate. More particularly, the impurities added to the capping layer 216 preferably are at least one of phosphorous (P), nitrogen (N), and oxygen (O). To add the impurities to the capping layer 216, at least one of PH₃ gas, NH₃ gas, and O₂ gas (i.e., an impurity source gas of a high concentration) preferably is supplied to a chamber in which the semiconductor substrate 200 is loaded. If at least one of the PH₃ gas, the NH₃ gas, and the O₂ gas is supplied to the chamber, different impurities are contained in the capping layer 216 depending on the type of the supplied impurity source gas. The capping layer 216 containing the impurities serves as a seed layer when forming the control gate.

The process of containing the impurities in the capping layer 216 preferably is performed in-situ in the same chamber after forming the capping layer 216.

Referring to FIG. 2H, the third conductive layer 218 for the control gate is formed over the capping layer 216. The third conductive layer 218 preferably comprises a doped polysilicon layer. In particular, if the third conductive layer 218 is formed over the capping layer 216 containing the impurities, the capping layer 216 containing the impurities serves as the seed layer, and so the third conductive layer 218 having grains of an uniform size can be formed.

Furthermore, the process of forming the third conductive layer 218 preferably is performed in-situ by using the same chamber after the process of adding the impurities to the capping layer 216 is performed.

Since the process of forming the capping layer 216, the process of containing the impurities, and the process of forming the third conductive layer 218 preferably are performed in-situ in the same chamber as described above, the turnaround time may be reduced.

In the process of forming the third conductive layer 218 as described above, voids can be prevented from occurring in the region between the protruded second conductive patterns 210a for floating gates. Since the generation of voids can be prevented, an increase of resistance of the control gate can be prevented, thereby improving reliability of the nonvolatile memory devices.

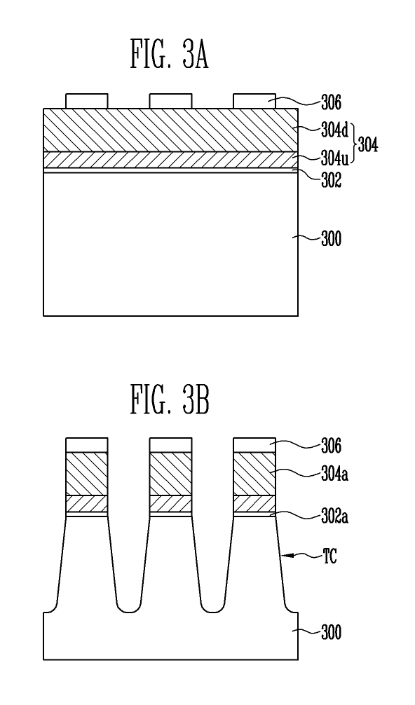

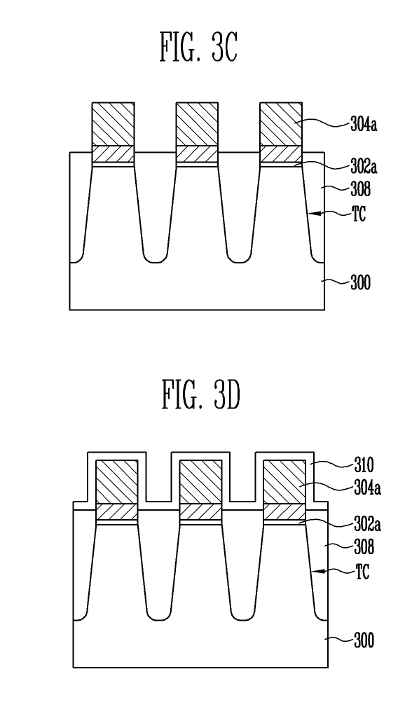

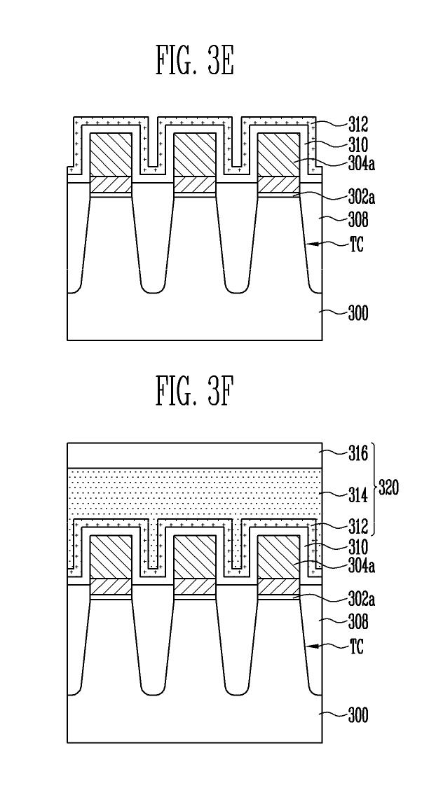

FIGS. 3A to 3F are cross-sectional views illustrating a method of manufacturing nonvolatile memory devices according to a third exemplary embodiment of this disclosure.

Referring to FIG. 3A, a gate insulating layer 302, a first conductive layer 304u and a second conductive layer 304d for floating gate 304, and isolation mask patterns 306 are formed over a semiconductor substrate 300. The gate insulating layer 302 preferably comprises an oxide layer. The first conductive layer 304u preferably comprises an undoped polysilicon layer. The second conductive layer 304d preferably comprises a doped polysilicon layer. One of monosilane (SiH₄), disilane (Si₂H₆) or dichlorosilane (SiH₂Cl₂) is used as a source gas during formation of the first and second conductive layers 304u and 304d. Furthermore, to form the first and second conductive layers 304u and 304d having a small and uniform nano sized grain, an additive gas may be used together with the source gas. For example, if NH₃ gas is used as the additive gas, nitrogen (N) is contained in the first and second conductive layers 304u and 304d. If C₂H₄ gas is used as the additive gas, carbon (C) is contained in the first and second conductive layers 304u and 304d. Impurity such as boron (B) or phosphorous (P) is implanted into the second conductive layer 304d. Thus, the second conductive layer 304d has a conductive characteristic. The isolation mask patterns 306 preferably comprise a nitride layer.

Referring to FIG. 3B, the second conductive layer 304d, the first conductive layer 304u and the gate insulating layer 302 are patterned by performing an etch process using the isolation mask pattern 306 as an etching mask, thereby exposing portions of the semiconductor substrate 300. Trenches TC are formed by etching the exposed portions of semiconductor substrate 300. Therefore, gate insulating patterns 302a and floating gates 304a are formed over the semiconductor substrate in active regions, and the trenches TC are formed over the semiconductor substrate in isolation regions.

Referring FIG. 3C, the trenches TC are filled with an insulating material, thereby forming isolation layers 308. More particularly, to fully fill the trenches TC, the insulating material covers the top surface of the isolation mask patterns 306. Next, a polishing process such as chemical mechanical polishing (CMP) is performed until the isolation mask patterns 306 are exposed, thereby isolating the active regions from each other by the insulating material filled in the trenches TC. The insulating materials in the trenches TC are isolation layers 308. The isolation mask patterns 306 are removed. It is desirable that a portion of the isolation layers 308 is etched to control the effective field height (EFH). Here, the gate insulating patterns 302a preferably are not exposed, and portions of the floating gates 304a are exposed.

Referring to FIG. 3D, a dielectric layer 310 is formed on the isolation layers 308 and the exposed surface of the floating gates 304a. The dielectric layer 310 preferably is formed by stacking an oxide layer, a nitride layer, and an oxide layer or by depositing a high-K layer.

Referring to FIG. 3E, a capping layer 312 for easily forming a control gate is formed along a surface of the dielectric layer 310. The capping layer 312 is formed using one of monosilane (SiH₄), disilane (Si₂H₆) or dichlorosilane (SiH₂Cl₂) as a source gas. To form the capping layer 312 comprising a thin and uniform amorphous silicon layer, the disilane (Si₂H₆) preferably is used. The capping layer 312 preferably is formed relatively thin by taking the aspect ratio between protruded floating gates into consideration. More particularly, the capping layer 312 preferably comprises an amorphous silicon layer which is formed to a temperature of 400° C. to 700° C. and to a thickness of 5 Å to 100 Å so that a gap between protruded floating gates is not fully filled.

Referring to FIG. 3F, a third conductive layer 314 for the control gate is formed over the capping layer 312. The third conductive layer 314 may be more uniformly formed over the capping layer 312 of amorphous layer than the dielectric layer 310. The third conductive layer 316 preferably comprises a doped polysilicon layer. If additives are contained in the third conductive layer 314 when impurities are injected into the third conductive layer 314, voids or seams may be removed during a subsequent annealing process. Thus, an additive gas is supplied in-situ in the chamber to include the additives in the third conductive layer 314 while the impurities are injected into the third conductive layer 314. The source gas comprises monosilane (SiH₄), disilane (Si₂H₆) or dichlorosilane (SiH₂Cl₂). It is desirable that the monosilane (SiH₄) is used when the third conductive layer 314 is formed. Impurities preferably comprise boron (B) or phosphorous (P). More particularly, various additive gases preferably are used to form a small and uniform grain of the third conductive layer 314. For example, NH₃ gas or C₂H₄ gas preferably is used. If NH₃ gas is used, nitrogen (N) as the additive is contained in the third conductive layer 314. If C₂H₄ gas is used, carbon (C) as the additive is contained in the third conductive layer 314. The additive such as nitrogen or carbon contained in the third conductive layer 314 preferably has a concentration of 1×10²¹ ions/cm³ to 5×10²² ions/cm³.

Next, the annealing process is performed to crystallize the third conductive layer 314 and the capping layer 312. Voids or seams may be removed during the annealing process. The annealing process is performed to a temperature of 800° C. to 1000° C. and N₂ gas atmosphere within 2 hours. The capping layer 312 and the third conductive layer 314 become a polysilicon by crystallizing during the annealing process. More particularly, the third conductive layer 314 which was an amorphous layer is changed to a crystallized polysilicon layer by the additive contained in the third conductive layer 314. Here, the voids or seams are dispersed and then changed to micro voids so that the defect by the voids or seams can be prevented from occurring in the region between the protruded floating gate. Furthermore, a turnaround time (TAT) may be improved by using single type equipment instead of a furnace for the annealing process.

Next, a metal layer 316 is further formed over the third conductive layer 314 to lower resistance so that a control gate comprises the capping layer 312, the third conductive layer 314 and the metal layer 316.

According to the disclosure, the capping layer is formed on a surface of the dielectric layer, and impurities for accelerating the formation of a conductive material for a control gate are added to the capping layer. Accordingly, the generation of voids can be prevented in the process of forming the control gate. Consequently, reliability of nonvolatile memory devices can be improved because deterioration of an electrical characteristic can be prevented.

What is claimed is:

1. A nonvolatile memory device, comprising:
a gate insulating layer, a floating gate and a dielectric layer sequentially formed over a semiconductor substrate;
a capping layer formed over the dielectric layer; and
a control gate formed over the capping layer, wherein the control gate includes polysilicon in which nitrogen or carbon is contained as an additive.

2. The nonvolatile memory device of claim 1, wherein the floating gate comprises an undoped polysilicon layer and a doped polysilicon layer formed over the undoped polysilicon layer.

3. The nonvolatile memory device of claim 1, further comprising additives which are contained in the floating gate.

4. The nonvolatile memory device of claim 1, wherein impurity is injected into the control gate.

5. The nonvolatile memory device of claim 4, wherein the impurity comprises boron (B) or phosphorous (P).

6. A nonvolatile memory device, comprising:
a gate insulating layer, a floating gate and a dielectric layer sequentially formed over a semiconductor substrate;
a capping layer formed over the dielectric layer; and
a control gate formed over the capping layer, wherein the control gate comprises a nano sized grain by containing an additive.

7. The nonvolatile memory device of claim 6, wherein the floating gate comprises an undoped polysilicon layer and a doped polysilicon layer formed over the undoped polysilicon layer.

8. The nonvolatile memory device of claim 6, further comprising additive which is contained in the floating gate.

9. The nonvolatile memory device of claim 8, wherein the additive comprises nitride (N) or carbon (C).

10. The nonvolatile memory device of claim 6, wherein the control gate includes impurity to have a conductive characteristic.

11. The nonvolatile memory device of claim 10, wherein the impurity comprises boron (B) or phosphorous (P).

12. A method of manufacturing nonvolatile memory devices, comprising:
forming a sequentially stacked gate insulating layer and a floating gate over a semiconductor substrate;
forming a dielectric layer along a surface of a whole structure including the floating gate;
forming a capping layer along a surface of the dielectric layer;
forming a conductive layer of an amorphous layer over the capping layer, wherein the conductive layer contains additives;
performing an annealing process to crystallize the capping layer and the conductive layer.

13. The method of claim 12, wherein the capping layer comprises an amorphous silicon layer.

14. The method of claim 12, comprising forming the capping layer using a disilane (Si2H6) gas as a source gas.

15. The method of claim 12, wherein the conductive layer comprises an amorphous doped silicon layer.

16. The method of claim 12, wherein the conductive layer is formed by using a source gas and an additive gas and injecting impurity.

17. The method of claim 16, wherein the source gas comprises monosilane (SiH₄) gas.

18. The method of claim 16, wherein the additive gas comprises NH3 gas or C2H4 gas.

19. The method of claim 18, wherein the conductive layer contains nitrogen as an additive when NH₃ gas is used, and contains carbon as the additive when C₂H₄ gas is used.

20. The method of claim 12, wherein boron or phosphorous are injected into the control gate.
